(19) United States
(12) Patent Application Publication
(10) Pub. No.: US 2017/0309772 A1
(43) Pub. Date: Oct. 26, 2017

(54) METHOD FOR MANUFACTURING A LARGE-AREA THIN FILM SOLAR CELL

(71) Applicant: National Tsing Hua University, Hsinchu City (TW)

(72) Inventors: Chih-Huang LAI, Hsinchu City (TW); Chung-Hao CAI, Hsinchu City (TW)

(21) Appl. No.: 15/275,862

(22) Filed: Sep. 26, 2016

(30) Foreign Application Priority Data
Apr. 22, 2016 (TW) 105112547

(51) Int. Cl. H01L 31/18

(52) U.S. Cl. CPC H01L 31/1828; H01L 31/186

(57) ABSTRACT

A method for manufacturing a large-area thin film solar cell includes the steps of: (a) forming a first contact layer on a substrate; (b) forming a multi-layer metal precursor film on the first contact layer, which includes the sub-steps of (b1) sputtering a first multinary metal precursor layer on the first contact layer, the first multinary metal precursor layer containing Cu, Ga and KF, and (b2) sputtering an In-containing precursor layer on the first multinary metal precursor layer; and (c) subjecting the multi-layer metal precursor film to selenization to form an absorber layer having a chalcopyrite phase.

### CROSS-REFERENCE TO RELATED APPLICATION

This application claims priority of Taiwanese Patent Application No. 105112547, filed on Apr. 22, 2016.

### FIELD

The disclosure relates to a method for manufacturing a thin film solar cell, and more particularly to a method for manufacturing a thin film solar cell having a large area.

### BACKGROUND

Among various types of solar cells, thin film solar cells have been paid much attention due to high photoelectric conversion efficiency thereof. The thin film solar cell includes a photoelectric material having a chalcopyrite phase (for example, Cu (In, Ga) Se₂, referred to as CIGS hereinafter), which is used as an absorber layer therein.

It is well known in the art that carrier recombination may be effectively prohibited by increasing an energy gap at an interface between the CIGS absorber layer and an upper/lower contiguous layer so that electrical properties including open circuit voltage and the like of the thin film solar cell may be enhanced. Therefore, in order to increase the energy gap at the interface between the CIGS absorber layer and the upper/lower contiguous layer, it is desirable to permit the CIGS absorber layer to have a normal grading bandgap or further to have a double grading bandgap of a “notch” profile in term of an in-depth bandgap variation via Ga-grading so that short circuit current density may be further enhanced. The CIGS absorber layer having the double grading bandgap may be produced by, for example, co-evaporation or sputtering.

In a conventional co-evaporation process, a substrate formed with a Mo metal layer thereon is disposed within a high-vacuum chamber of an in-line co-evaporation plant. Output powers of a plurality of electrode crucibles respectively carrying Cu, In, Ga, and Se are continuously controlled during the co-evaporation process so as to adjust flows of Cu, In, Ga, and Se gases respectively evaporated from the electrode crucibles. A CIGS absorber layer having a double grading bandgap of a “notch” profile is thus formed on the Mo metal layer.

In “Potassium-induced surface modification of Cu(In,Ga)Se₂ thin films for high-efficiency solar cells,” Nature Materials, 12(2013), 1107-1111, Adrian Chirila et al. disclose a new sequential post-deposition treatment (PDT) of a CIGS absorber layer with sodium fluoride and potassium fluoride that enables fabrication of flexible photovoltaic devices with a remarkable conversion efficiency due to modified interface properties and mitigation of optical losses in a CdS buffer layer. KF-PDT-induced CIGS surface modification facilitates Cd diffusion in a Cu-depleted surface of the CIGS absorber layer, and results in an improved CIGS/CdS heterojunction quality. However, neither the co-evaporation process nor the post-deposition treatment maybe used for manufacturing a large-area thin film solar cell.

Referring to FIG. 1, in a conventional sputtering process, a Mo metal layer 100 is deposited on a soda-lime glass substrate 10, and a CuGa metal film 11 is deposited on the Mo metal layer 100 by sputtering and an In metal film 12 is then deposited on the CuGa metal film 11 by sputtering so as to form a multilayer precursor film 13 on the Mo metal layer 100. The multilayer precursor film 13 is subjected to a sulfurlization-after-selenization treatment followed by annealing to form a CIGS absorber layer having a double grading bandgap of a notch profile. However, the sulfurization process required in the sulfurization-after-selenization treatment is time-consuming.

Therefore, it is desirable in the art to develop a simplified process for manufacturing a large-area thin film solar cell.

### SUMMARY

An object of the disclosure is to provide a simplified process for manufacturing a large-area thin film solar cell.

According to the disclosure, there is provided a method for manufacturing a large-area thin film solar cell, which includes the steps of:

(a) forming a first contact layer on a substrate;

(b) forming a multi-layer metal precursor film on the first contact layer, which includes the sub-steps of:
(b1) sputtering a first multinary metal precursor layer on the first contact layer, the first multinary metal precursor layer containing Cu, Ga and KF, and
(b2) sputtering an In-containing precursor layer on the first multinary metal precursor layer; and

(c) subjecting the multi-layer metal precursor film to selenization to form an absorber layer having a chalcopyrite phase.

In the method for manufacturing a large-area thin film solar cell of the disclosure, after forming the multi-layer metal precursor film by sputtering on the first contact layer the first multinary metal precursor layer containing Cu, Ga and KF, and then sputtering the In-containing precursor layer on the first multinary metal precursor layer, the absorber layer having a chalcopyrite phase may be formed directly via selenization. Sulfurization required in the conventional sputtering process is not required in the method of the disclosure. Therefore, the method of the disclosure is simplified and time-saving.

### BRIEF DESCRIPTION OF THE DRAWINGS

Other features and advantages of the disclosure will become apparent in the following detailed description of the embodiment (s) with reference to the accompanying drawings, of which:

FIG. 1 is a schematic view illustrating a multi-layer metal precursor film formed by a conventional sputtering process;

FIGS. 2 and 3 are schematic views illustrating consecutive steps of a first embodiment of a method for manufacturing a large-area thin film solar cell according to the disclosure;

FIG. 4 is a schematic view illustrating a step of forming a multi-layer metal precursor film in a second embodiment of a method for manufacturing a large-area thin film solar cell according to the disclosure;

FIG. 5 is a schematic view illustrating a step of forming a multi-layer metal precursor film in a third embodiment of a method for manufacturing a large-area thin film solar cell according to the disclosure;

FIG. 6 is a schematic view illustrating a step of forming a multi-layer metal precursor film in a fourth embodiment of a method for manufacturing a large-area thin film solar cell according to the disclosure;

FIG. 7 is a schematic view illustrating a step of forming a multi-layer metal precursor film in a fifth embodiment of a method for manufacturing a large-area thin film solar cell according to the disclosure;

FIG. 8 is a schematic view illustrating a step of forming a multi-layer metal precursor film in a sixth embodiment of a method for manufacturing a large-area thin film solar cell according to the disclosure;

FIG. 9 is a schematic view illustrating a step of forming a multi-layer metal precursor film in a seventh embodiment of a method for manufacturing a large-area thin film solar cell according to the disclosure;

FIG. 10 illustrates a secondary ion mass spectrogram showing Ga depth profiles in absorber layers of thin film solar cells manufactured in Example 1 and Comparative Examples 1 and 2;

FIG. 11 illustrates spectroscopy compositional depth profiles in an absorber layer of a thin film solar cell manufactured in Example 2 by X-ray photoelectron spectroscopy;

FIG. 12 illustrates a plot of current density vs. voltage to show electrical properties of the thin film solar cells manufactured in Example 1 and Comparative Examples 1 and 2;

FIG. 13 illustrate a plot of external quantum efficiency vs. wavelength of the thin film solar cells manufactured in Example 1 and Comparative Examples 1 and 2; and

FIG. 14 illustrates a plot of current density vs. voltage to show electrical properties of the thin film solar cells manufactured in Examples 1 and 2.

### DETAILED DESCRIPTION

Before the disclosure is described in greater detail, it should be noted that where considered appropriate, reference numerals or terminal portions of reference numerals have be en repeated among the figures to indicate corresponding or analogous elements, which may optionally have similar characteristics.

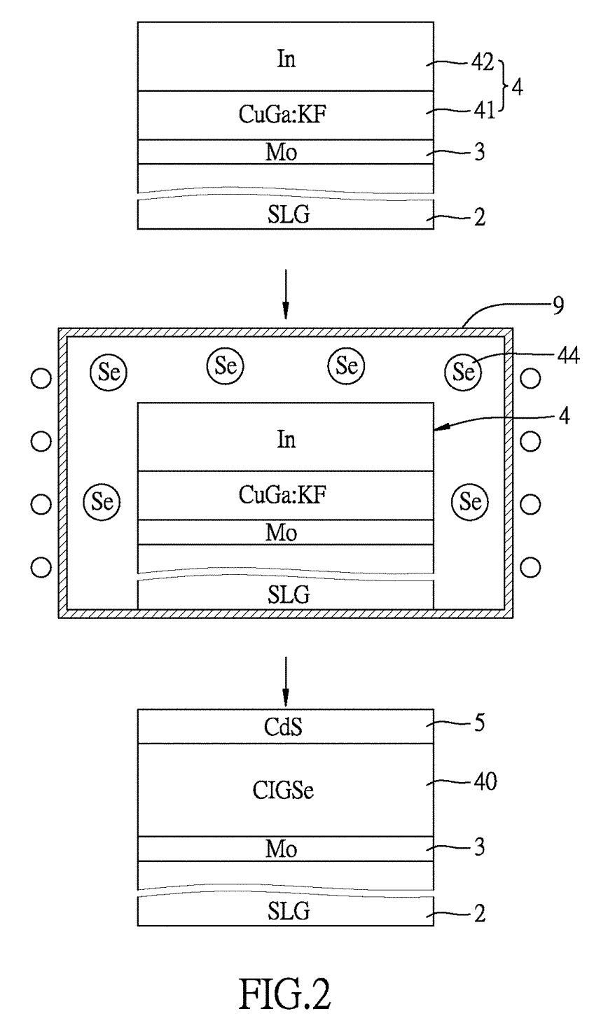

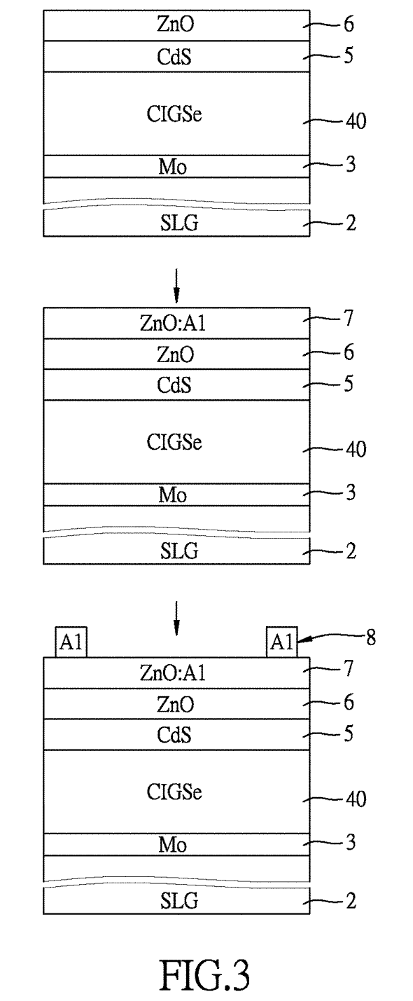

Referring to FIGS. 2 and 3, the first embodiment of a method for manufacturing a large-area thin film solar cell according to the disclosure includes following steps (a), (b), (c), (d), (e), (f), and (g).

In step (a), a first contact layer 3 (i.e., a Mo metal layer) is formed on a substrate 2 by sputtering. In the embodiment, the substrate 2 is a soda-lime glass substrate which is a Na-containing substrate.

In step (b), a multi-layer metal precursor film 4 is formed on the first contact layer 3 by following sub-steps (b1) and (b2).

In sub-step (b1), a first multinary metal precursor layer 41 is sputtered on the first contact layer 3. The first multinary metal precursor layer 41 contains Cu, Ga and KF. The sub-step (b1) is performed by sputtering from a target containing Ga in an amount ranging from 10 atom% to 40 atom%, KF in an amount ranging from 0.5 atom % to 10 atom %, and Cu in a balance amount.

In sub-step (b2), an In-containing precursor layer 42 is sputtered on the first multinary metal precursor layer 41. The sub-step (b2) is performed by sputtering from an In target.

In step (c), the multi-layer metal precursor film 4 is subjected to selenization to form an absorber layer 40 having a chalcopyrite phase. The selenization is performed for 20 minutes in the presence of an inert gas atmosphere and a selenium source and is followed by annealing. Specifically, the multi-layer metal precursor film 4 is disposed in a graphite box (not shown) in an annealing furnace 9. The graphite box carries Se powders. Argon (Ar) gas is then introduced in the annealing furnace 9, and Se powders are gasified into Sc gas at 550° C., 1 atm so as to subject the multi-layer metal precursor film 4 to selenization to form the absorber layer 40 having a chalcopyrite phase.

In the first embodiment, the absorber layer 40 has a thickness (D), the first multinary metal precursor layer 41 has a thickness (d1), and the In-containing precursor layer 42 has a thickness (d2). D is larger than 0.8 μm, and a ratio of d1/d2 is preferably not less than 0.25, and more preferably ranges from 0.25 to 1.2.

In step (d), a first buffer layer 5 of CdS is formed on the absorber layer 40 by chemical bath deposition.

In step (e), a second buffer layer 6 of ZnO is formed on the first buffer layer 5 by radio frequency sputtering.

In step (f), a transparent conductive layer 7 is formed on the second buffer layer 6 by radio frequency sputtering. The transparent conductive layer 7 is an Al-doped ZnO layer.

Instep (g), a second contact layer 8 of Al is formed on the transparent conductive layer 7 by e-beam evaporation.

It is found from the aforesaid description that the absorber layer 40 having a chalcopyrite phase may be formed directly via selenization and that sulfurization required in the conventional sputtering process is not required in the method of the disclosure.

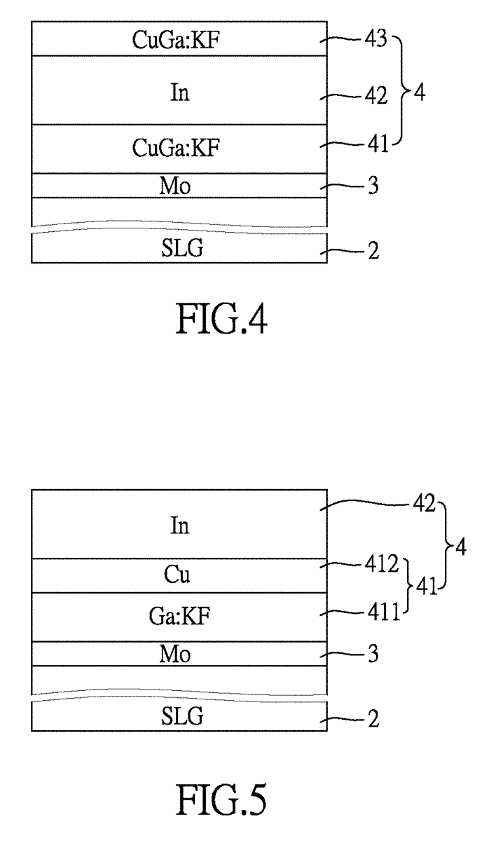

Referring to FIG. 4, the second embodiment of a method for manufacturing a large-area thin film solar cell according to the disclosure is substantially similar to the first embodiment except that step (b) in the second embodiment further includes, after sub-step (b2), sub-step (b3) of sputtering from the target containing Cu, Ga and KF to form a second multinary metal precursor layer 43 on the In-containing precursor layer 42. The second multinary metal precursor layer 43 contains Cu, Ga and KF.

In the second embodiment, the absorber layer 40 has a thickness (D), the first multinary metal precursor layer 41 has a thickness (d1), the In-containing precursor layer 42 has a thickness (d2), and the second multinary met al precursor layer 43 has a thickness (d3). D is larger than 0.8 μm, a ratio of d1/d3 is in a range from 0.5 to 6, and a ratio of (d1+d3)/d2 is preferably not less than 0.25, and more preferably ranges from. 0.25 to 1.2.

Referring to FIG. 5, the third embodiment of a method for manufacturing a large-area thin film solar cell according to the disclosure is substantially similar to the first embodiment except that the first multinary metal precursor layer 41 in the third embodiment includes a first metal precursor sub-layer 411 formed on the first contact layer 3 and containing Ga and KF, and a second metal precursor sub-layer 412 formed on the first metal precursor sub-layer 411 and containing Cu. Sub-step (b1) in the third embodiment is performed by sputtering from a target containing Ga and KF to form the first metal precursor sub-layer 411, and sputtering from a target containing Cu to form the second metal precursor sub-layer 412.

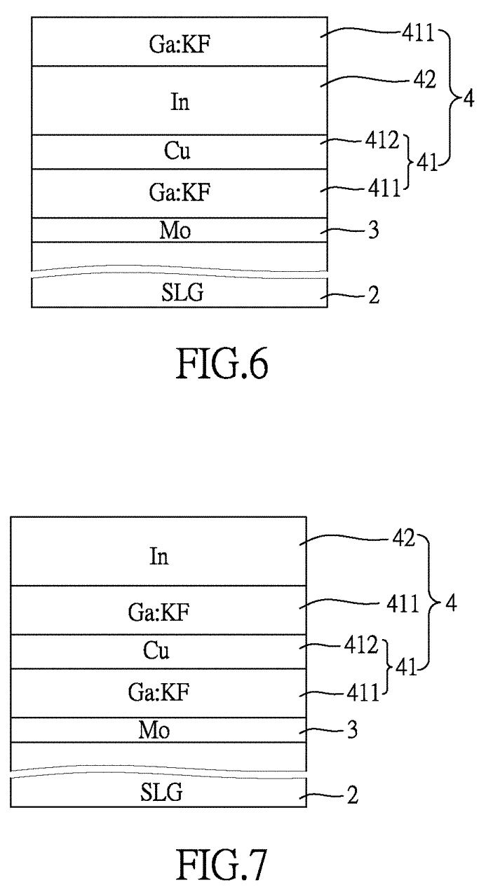

Referring to FIG. 6, the fourth embodiment of a method for manufacturing a large-area thin film solar cell according to the disclosure is substantially similar to the third embodiment except that step (b) in the fourth embodiment further includes, after sub-step (b2), sub-step (b4) of sputtering from the target including Ga and KF to form another one of the first metal precursor sub-layer 411 on the In-containing precursor layer 42.

Referring to FIG. 7, the fifth embodiment of a method for manufacturing a large-area thin film solar cell according to the disclosure is substantially similar to the third embodiment except step (b) in the fifth embodiment further includes sub-step (b4) of sputtering from the target including Ga and KF after sub-step (b1) and prior to sub-step (b2) to form another one of the first metal precursor sub-layer 411 on the second metal precursor sub-layer 412.

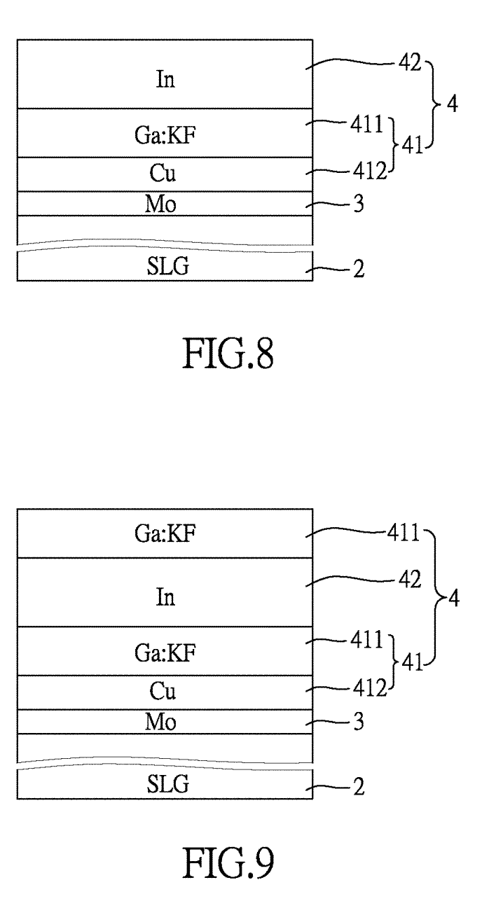

Referring to FIG. 8, the sixth embodiment of a method for manufacturing a large-area thin film solar cell according to the disclosure is substantially similar to the first embodiment except that the first multinary metal precursor layer 41 in the sixth embodiment includes the first metal precursor sub-layer 411 which is contiguous to the In-containing precursor layer and which contains Ga and KF, and the second metal precursor sub-layer 412 which is contiguous to the first contact layer 3 and which contains Cu sub-step (b1) in the sixth embodiment is performed by sputtering from a target containing Cu to form the second metal precursor sub-layer 412 on the first contact layer 3 and sputtering from a target containing Ga and KF to form the first metal precursor sub-layer 411 on the second metal precursor sub-layer 412.

Referring to FIG. 9, the seventh embodiment of a method for manufacturing a large-area thin film solar cell according to the disclosure is substantially similar to the sixth embodiment except that step (b) in the seventh embodiment further includes, after sub-step (b2), sub-step (b4) of sputtering from the target including Ga and KF to form another one of the first metal precursor sub-layer 411 on the In-containing precursor layer 42.

### EXAMPLE 1

The large-area thin film solar cell in Example 1 was manufactured according to the first embodiment described above.

A Mo contact layer (i.e., the first contact layer 3 in the first embodiment) having a thickness of 900 nm was deposited on a cleansed soda-lime glass substrate by direct current sputtering. A CuGa:KF layer (i.e., the first multinary metal precursor layer 41 in the first embodiment) having a thickness of 300 nm was formed on the Mo contact layer by sputtering from a target containing Cu, Ga and KF. An In layer (i.e., In-containing pre cursor layer 42 in the first embodiment) having a thickness of 550 nm was formed on the CuGa:KF layer by sputtering from an In target so that a multi-layer metal precursor film composed of the CuGa:KF layer and the In layer was formed on the Mo contact layer.

The multi-layer metal precursor film was then subjected to selenization at 550° C., 1 atm for 20 minutes followed by annealing to 100° C. to form an absorber layer having a chalcopyrite phase and having a thickness of 2 μm.

A CdS layer (i.e., the first buffer layer 5 in the first embodiment) having a thickness of 60 nm was formed on the absorber layer by chemical bath deposition. A ZnO layer (i.e., the second buffer layer 6 in the first embodiment) having a thickness of 50 nm was formed on the CdS layer by radio frequency sputtering. A ZnO:Al layer (i.e. the transparent conductive layer 7 in the first embodiment) having a thickness of 200 nm is formed on the ZnO layer by radio frequency sputtering. A patterned Al layer (i.e., the second contact layer 8 in the first embodiment) was formed on the ZnO:Al layer by e-beam evaporation and photolithography to obtain a large-area thin film solar cell.

### EXAMPLE 2

The large-area thin film solar cell in Example 2 was manufactured according to the second embodiment described above. The procedure of Example 1 was repeated except that another CuGa:KF layer (i.e., the second multinary metal precursor layer 43 in the second embodiment) having a thickness of 60 nm was formed on the In-containing layer by sputtering from the target containing Cu, Ga and KF, and that the multinary metal precursor layer 41 in Example 2 has a thickness of 240 nm.

### COMPARATIVE EXAMPLE 1

The large-area thin film solar cell in Comparative Example 1 was manufactured by repeating the procedure of Example 1 except that a CuGa layer having a thickness of 300 nm was formed on the Mo contact layer by sputtering from a target containing Cu and Ga. Therefore, the first multinary metal precursor layer in the large-area thin film solar cell manufactured in Comparative Example 1 is the CuGa layer which does not contain KF.

### COMPARATIVE EXAMPLE 2

The large-area thin film solar cell in Comparative Example 2 was manufactured by repeating the procedure of Example 1 except that a CuGa:NaF layer having a thickness of 300 nm was formed on the Mo contact layer by sputtering from a target containing Cu, Ga and NaF. The first multinary metal precursor layer in the large-area thin film solar cell manufactured in Comparative Example 2 is the CuGa:NaE layer, rather than the CuGa:KF layer.

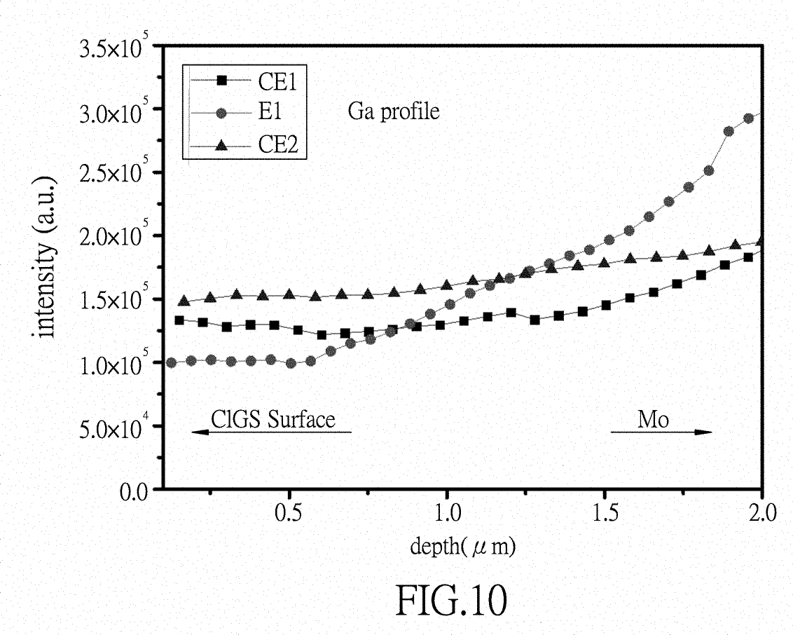

FIG. 10 illustrates Ga depth profiles in the absorber layers of the thin film solar cells manufactured in Example 1 and Comparative Examples 1 and 2. As shown in FIG. 10, the amount of Ga in the absorber layer of each of the large-area thin film solar cells of Comparative Examples 1 and 2 is slightly increased through the absorber layer from the surface thereof toward the Mo layer. However, the amount of Ga in the absorber layer of the large-area thin film solar cell of Example 1 is significantly increased through the absorber layer from the surface thereof toward the Mo layer. It is thus demonstrated that an energy gap at an interface between the absorber layer and the Mo layer in the large-area thin film solar cell of Example 1 is significantly increased so that the carrier recombination at the interface between the absorber layer and the Mo layer may be effectively prohibited and the electrical properties including open circuit voltage and short circuit current density of the large-area thin film solar cell may be enhanced.

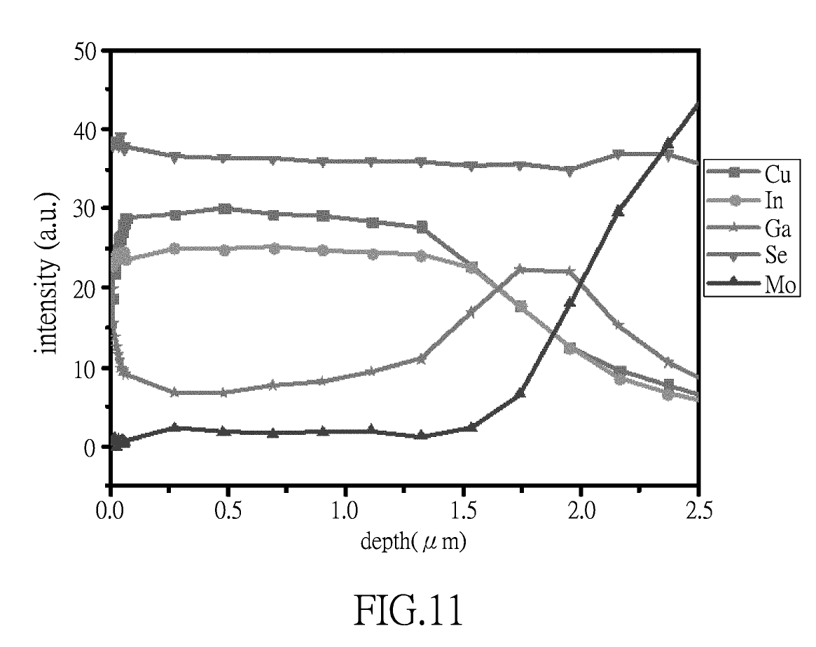

FIG. 11 illustrates the depth profiles of Cu, In, Ga, Se, and Mo in the absorber layer of the thin film solar cell manufactured in Example 2, as shown in FIG. 11, the amount of Ga in the absorber layer of the large-area thin film solar cell of Example 2 is decreased through the absorber layer from the surface thereof toward the depth of about 0.25 μm, and is then increased through the absorber layer from the depth of about 0.25 μm toward the Mo layer. That is, the absorber layer of the large-area thin film solar cell of Example 2 has a double Ga-grading of a notch profile. It is thus demonstrated that the absorber layer in the thin film solar cell of Example 2 has an double grading energy gap so that the carrier recombination at the interface between the absorber layer and the Mo layer maybe further effectively prohibited and the electrical properties including open circuit voltage and short circuit current density of the large-area thin film solar cell may be further enhanced.

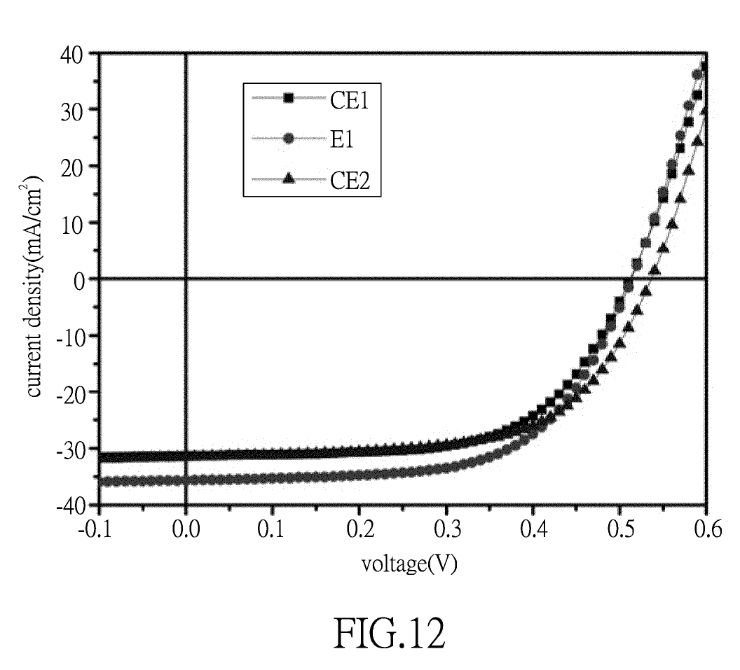

FIG. 12 illustrates a plot of current density vs. voltage of the thin film solar cells manufactured in Example 1 and Comparative Examples 1 and 2. As shown in FIG. 12 and Table 1, open circuit voltages (Voc) of the large-area thin film solar cells of Comparative Examples 1 and 2 are 512 mV and 536 mV, respectively, and open circuit voltage (Voc) of the large-area thin film solar cell of Example 1 is 514 mV. Short circuit current densities (Jsc) of the large-area thin film solar cells of Comparative Examples 1 and 2 are 31.34 mA/cm² and 31.55 mA/cm², respectively, and short circuit current density (Jsc) of the large-area thin film solar cell of Example 1 is 35.63 mA/cm², which is relatively high compared to those in Comparative Examples 1 and 2.

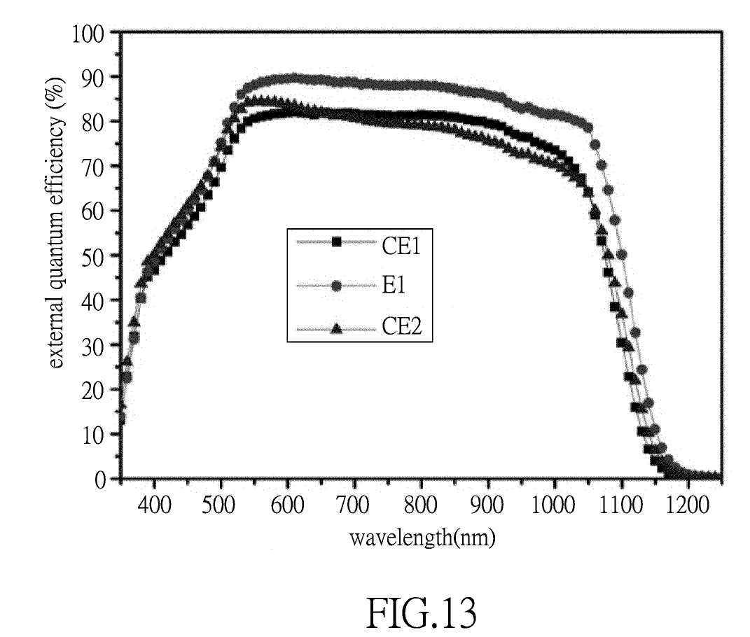

Referring to FIG. 13, an average external quantum efficiency in a wavelength range from 500 nm to 1000 nm of the large-area thin film solar cell of Example 1 is about 87%. However, the average external quantum efficiency in a wavelength range from 500 nm to 1000 nm of each of the large-area thin film solar cells of Comparative Examples 1 and 2 is merely about 80%.

In Example 1, the multi-layer metal precursor film composed of an CuGa:KF layer and an In layer was formed on the Mo contact layer, the absorber layer of the large-area thin film solar cell manufactured thereby has a relatively sharp Ga-grading. An internal electric field is formed in the absorber layer of the large-area thin film solar cell of Example 1 to facilitate transportation of electrons to the CdS layer so as to enhance the external quantum efficiency. In addition, the absorber layer of the large-area thin film solar cell of Example 1 has a low Ga amount at the surface thereof, which corresponds to a low energy gap so that the absorber layer may absorb light having a relatively long wavelength range from 1100 nm to 1150 nm. Therefore, the large-area thin film solar cell of Example 1 may have a relatively large short circuit current density compared to those of the large-area thin film solar cells of Comparative Examples 1 and 2.

In addition, as shown in Table 1, photoelectric conversion efficiencies (PCE) of the large-area thin film solar cells of Comparative Examples 1 and 2 are 9.94% and 10.40%, respectively. However, the photoelectric conversion efficiency (PCE) of the large-area thin film solar cell of Example 1 is 11.21%, which is relatively large compared to those of the large-area thin film solar cells of Comparative Examples 1 and 2.

TABLE 1

| | Voc (mV) | Jsc (mA/cm²) | PCE (%) |
|---|---|---|---|
| CE1 | 512 | 31.34 | 9.94 |
| CE2 | 536 | 31.55 | 10.40 |
| E1 | 514 | 35.63 | 11.21 |
| E2 | 533 | 35.97 | 12.24 |

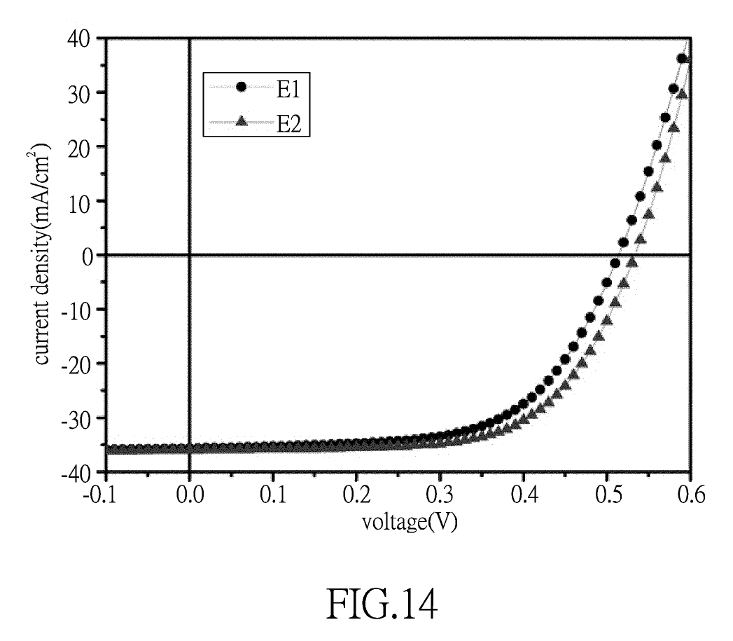

Referring to FIG. 14, in Example 2, the multi-layer metal precursor film composed of an In layer and two CuGa:KF layers sandwiching the In layer was formed on the Mo contact layer, the absorber layer of the large-area thin film solar cell manufactured thereby has a double grading bandgap of a notch profile due to a double Ga-grading of a notch profile shown in FIG. 11. As shown in Table 1, the large-area thin film solar cell manufactured in Example 2 has an open circuit voltage (Voc) of 533 mV, a short circuit current density (Jsc) of 35.97 mA/cm², and a photoelectric conversion efficiency (PCE) of 12.24%.

As demonstrated from the results of the illustrated examples, in Examples 1 and 2, KF is introduced into the multi-layer metal precursor film by sputtering from a target containing Cu, Ga, and KF so that the absorber layers of the large-area thin film solar cells manufactured thereby have a normal grading bandgap (Example 1) or even a double grading bandgap (Example 2) so that the performances including short circuit current density and photoelectric conversion efficiency of the large-area thin film solar cells may be enhanced.

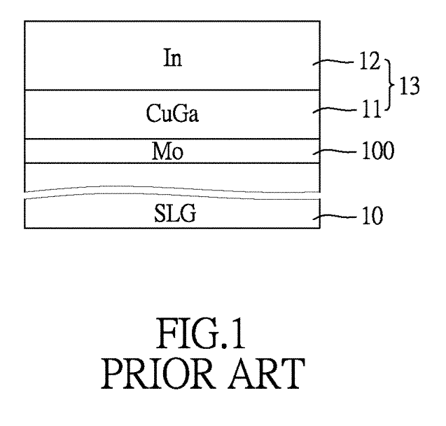

In addition, the absorber layer, which gas a double grading bandgap, of the large-area thin film solar cell of Example 2 may be formed by sputtering followed by selenization. Sulfurization required in the conventional sputtering process shown in FIG. 1 may be omitted. Therefore, the method for manufacturing a large-area thin film solar cell of the disclosure is relatively simple.

Furthermore, although it is described in the aforesaid post-deposition treatment disclosed by Adrian Chirila et al. that a KF film is deposited by evaporation. Such deposition of KF film is performed in the presence of Se after an CIGS absorber layer is formed. Therefore, the method disclosed by Adrian Chirila et al. is rather complicated. In addition, in the method disclosed by Adrian Chirila et al., the CIGS absorber layer is formed on a commercially available polyimide film by co-evaporation. Therefore, it is not suitable for manufacturing a large-area thin film solar cell.

In the description above, for the purposes of explanation, numerous specific details have been set forth in order to provide a thorough understanding of the embodiment(s). It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

1. A method for manufacturing a large-area thin film solar cell, comprising the steps of:
(a) forming a first contact layer on a substrate;
(b) forming a multi-layer metal precursor film on the first contact layer, which includes the sub-steps of:
(b1) sputtering a first multinary metal precursor layer on the first contact layer, the first multinary metal precursor layer containing Cu, Ga and KF, and
(b2) sputtering an In-containing precursor layer on the first multinary metal precursor layer; and
(c) subjecting the multi-layer metal precursor film to selenization to form an absorber layer having a chalcopyrite phase.

2. The method according to claim 1, wherein the substrate is a Na-containing substrate.

3. The method according to claim 1, wherein sub-step (b1) is performed by sputtering from a target containing Cu, Ga and KF.

4. The method according to claim 3, wherein step (b) further includes, after sub-step (b2), sub-step (b3) of sputtering from the target containing Cu, Ga and KF to form a second multinary metal precursor layer on the In-containing precursor layer, the second multinary metal precursor layer containing Cu, Ga and KF.

5. The method according to claim 1, wherein the first multinary metal precursor layer includes a first metal precursor sub-layer formed on the first contact layer and containing Ga and KF, and a second metal precursor sub-layer formed on the first metal precursor sub-layer and containing Cu, sub-step (b1) being performed by sputtering from a target containing Ga and KF to form the first metal precursor sub-layer, and sputtering from a target containing Cu to form the second metal precursor sub-layer.

6. The method according to claim 5, wherein step (b) further includes, after sub-step (b2), sub-step (b4) of sputtering from the target including Ga and KF to form another one of the first metal precursor sub-layer on the In-containing precursor layer.

7. The method according to claim 5, wherein step (b) further includes sub-step (b4) of sputtering from the target including Ga and KF after sub-step (b1) and prior to sub-step (b2) to form another one of the first metal precursor sub-layer on the second metal precursor sub-layer.

8. The method according to claim 1, wherein the first multinary metal precursor layer includes a first metal precursor sub-layer being contiguous to the In-containing precursor layer and containing Ga and KF, and a second metal precursor sub-layer being contiguous to the first contact layer and containing Cu, sub-step (b1) being performed by sputtering from a target containing Cu to form the second metal precursor sub-layer on the first contact layer and sputtering from a target containing Ga and KF to form the first metal precursor sub-layer on the second metal precursor sub-layer.

9. The method according to claim 8, wherein step (b) further includes, after sub-step (b2), sub-step (b4) of sputtering from the target including Ga and KF to form another the first metal precursor sub-layer on the In-containing precursor layer.

10. The method according to claim 1, wherein the absorber layer has a thickness (D), the first multinary metal precursor layer has a thickness (d1), and the In-containing precursor layer has a thickness (d2), D being larger than 0.8 μm, and a ratio of d1/d2 being not less than 0.25.

11. The method according to claim 4, wherein the absorber layer has a thickness (D), the first multinary metal precursor layer has a thickness (d1), the In-containing precursor layer has a thickness (d2), and the second multinary metal precursor layer has a thickness (d3), D being larger than 0.8 μm, a ratio of d1/d3 being in a range from 0.5 to 6, and a ratio of (d1+d3)/d2 being not less than 0.25.

12. The method according to claim 1, wherein the selenization is performed in the presence of an inert gas atmosphere and a selenium source and is followed by annealing.

13. The method according to claim 1, further comprising the steps of:
(d) forming a first buffer layer on the absorber layer;
(e) forming a second buffer layer on the first buffer layer;
(f) forming a transparent conductive layer on the second buffer layer; and
(g) forming a second contact layer on the transparent conductive layer.
